(19) United States
(12) Patent Application Publication
(10) Pub. No.: US 2013/0265717 A1
(43) Pub. Date: Oct. 10, 2013

(54) Ultrafine particle removal system in printer exhaust

(71) Applicant: Christopher Francois David Watts, St. Albans (GB)

(72) Inventor: Christopher Francois David Watts, St. Albans (GB)

(73) Assignee: Xerox Corporation, Norwalk, CT (US)

(21) Appl. No.: 13/441,339

(22) Filed: Apr. 6, 2012

(51) Int. Cl. H05K 7/20

(52) U.S. Cl. 361/694

(57) ABSTRACT

A printing device having ultrafine particle (UFP) emissions is disclosed which includes an UFP particle removal assembly comprising a fluid conduit having a printing device emission input and output and an other fluid input and output wherein an emission portion of the conduit is affected by the other fluid portion and communication of the other fluid through the removal assembly effects a condensation/coalescence of the UFP emissions between the emission input and output for a reduction in UFP content of printing device emissions at the printing device emission output.

### BACKGROUND

The field of the present embodiments is directed to printing devices and, more particularly, control of the emissions exhausted from photocopiers and the like. More particularly, the present embodiments are directed to reduce ultrafine particles (UFPs) and volatile organic compounds (VOC) emissions from the exhaust of the system, although those skilled in the art will appreciate that the embodiments are applicable to other types of electronic equipment.

Current photocopier products emit UFPs at high rates, peaking at over 250,000 counts within prescribed test print cycles.

The majority of UFPs emitted from such machines comprise water vapor released by the fuser heat, the water being originally contained in the paper, or the VOCs from materials such as the fuser web oil. Fusers are typically lubricated using silicone oil. These UFPs usually exist in a gas or liquid (vapor) phase and are transported out of the machine in cooling airstreams, coalesce and are counted as particles by particle counters.

Industry standards and regulations continue to demand emission quality improvements by reducing the UFP and VOC content in exhaust emissions. Thus there is a need for methods and systems to address and improve photocopier, and other electric equipment, exhaust emission quality.

### BRIEF DESCRIPTION

The preferred embodiments exploit structure and methods for effecting surface condensation and coalescence of the UFPs on cooled surfaces within the machine to reduce UFP and VOC emissions from the machine. More particularly, a UFP particle removal assembly effects a cross-flow between cooling ambient air and the device exhaust emissions through an aluminum honeycomb so that heat transfer through the honeycomb walls effect condensation and/or coalescence through exhaust cooling for improved reduction and control of the UFPs.

More particularly, the subject embodiments comprise a printing device having UFP emissions including an UFP particle removal assembly. The assembly comprises a fluid conduit having a printing device emission input and output and an other fluid input and output wherein an emission portion of the conduit is affected by the other fluid portion and communication of the other fluid through the removal assembly effects a condensation/coalescence of the UFP emissions between the emission input and output for a reduction in UFP content of printing device emissions at the printing device emission output. The fluid conduit includes an interface between the emission portion and the other fluid portion for heat transfer from the emissions to the other fluid.

### BRIEF DESCRIPTION OF THE DRAWINGS

FIG. 1 is an elevated view of the cross-flow assembly showing a plurality of fluid conduits in a first direction, and a plurality of alternating second conduits in a second direction;

FIG. 2 is a portion of the assembly of FIG. 1;

FIG. 3 is a graphical representation of humidity and temperature reduction of exhaust through the subject particle removal assembly; and,

FIG. 4 is a block diagram of a printing device including a subject particle removal assembly.

### DETAILED DESCRIPTION

The subject embodiments are directed to the exploitation of surface condensation and coalescence of the UFPs on cooled surfaces within an exhaust assembly to a printing machine to reduce UFP and VOC emissions from the machine. More specifically, the use of a dual direction or “cross-flow” expanded aluminum honeycomb structure as the principal componentry of the removal assembly effectively controls, through condensation and/coalescence, the ultrafine particle reduction in exhaust emissions.

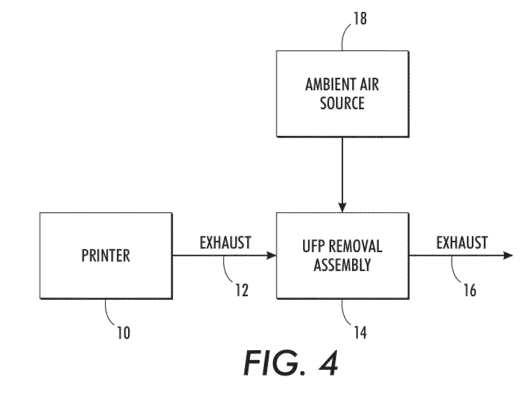

With particular reference to FIG. 4, it can be seen that a printer 10 includes an exhaust comprising air that is exposed to various printer components for purposes such as cooling or cleansing, but such exhaust can include undesirable elements such as UFPs and VOCs as noted above. The subject embodiments include the notion of capturing the exhaust 12 from the printer in a UFP removal assembly 14 which effects a temperature reduction and humidity reduction of the exhaust 12 thereby causing condensation and coalescence in the exhaust 12 to effectively reduce UFPs and VOCs from the UFP removal assembly 14 and its exhaust 16. As will be explained in more detail below, the desired condensation/coalescence is primarily caused by exposing printer exhaust 12 to a heat transfer process with an interfaced forced ambient air source 18 so that temperature and humidity can be withdrawn from the printer exhaust 12 by ambient air for cooling.

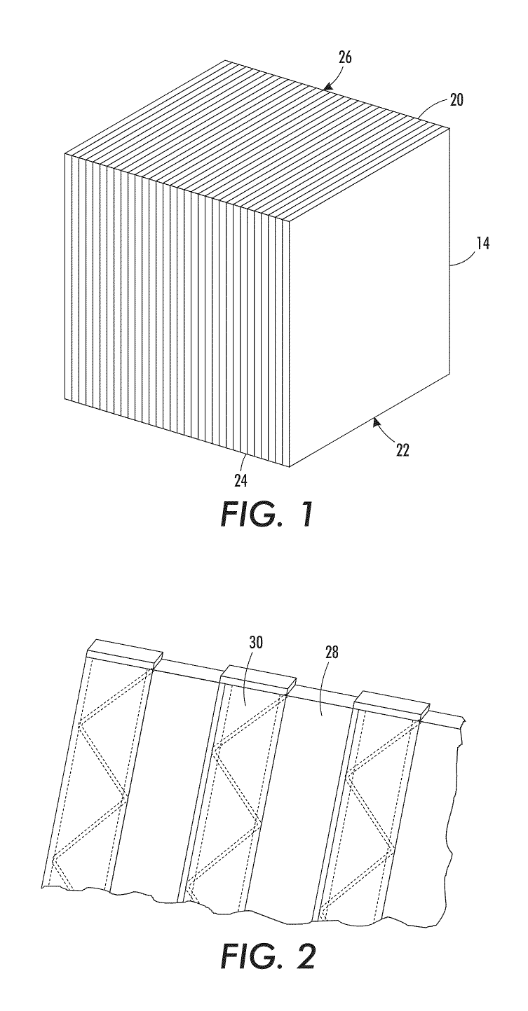

With particular reference to FIGS. 1 and 2, an embodiment of an UFP particle removal assembly is shown having a forced cooled aluminum surface, in a form of a dual direction expanded aluminum honeycomb to collect the UFPs, and thus reduce the UFP emission rates.

Honeycombs (such as those made of paper or aluminum) are made by a multi-stage process. Large thin sheets of the material (usually 1.2×2.4 m) are printed with alternating, parallel, thin strips of adhesive and the sheets are then stacked in a heated press while the adhesive cures. In the case of aluminum honeycomb, the stack of sheets is then sliced through its thickness. The slices (known as “block form”) are later gently stretched and expanded to form the sheet of continuous hexagonal cell shapes. The result is that air passing through the assembly 14 from one side 20 can only be emitted through an opposed output side 22. In addition, air entering from an orthogonal direction at side 24 can only exit through outputs 26. The result is a plurality of cross-flow planes each sealed from its adjacent plane so that the air in the first plane flows in an orthogonal direction from the air in any adjacent plane. Air flows in a first direction through conduit 28 and exhaust through an orthogonal direction in conduit 30.

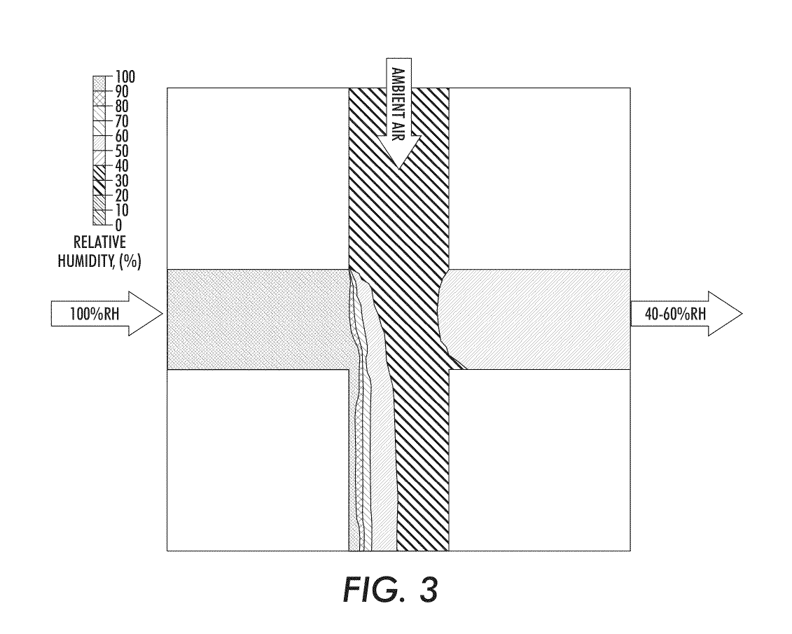

In the subject embodiments, the UFP exhaust is directed so that the interface between the emission portion of the exhaust and the other fluid portion, such as ambient air, will flow orthogonally, respectively. Thus, as the exhaust air 12 flows through the assembly 14 it will be effectively cooled by the aluminum walls of the assembly 14 due to the flow of the cooling air on the opposite side of a wall from which the exhaust air is passing. With particular reference to FIG. 3, it can be seen that a typical result of the implementation of such a UFP removal assembly on typical printer exhaust will cause a 40-60% reduction in relative humidity with a 5° drop in temperature degrees centigrade.

The model boundary conditions were defined as follows (with associated results):
horizontal duct left hand side was an inlet to the model (0.01 m3/hr @27° C., 100% RH)
horizontal duct right hand side was an outlet from the model (Initial condition 22° C., 50% RH)
vertical duct top was an inlet to the model (0.1 m3/hr @22° C., 40% RH)
vertical duct bottom was an outlet from the model (Initial condition 22° C., 50% RH)
   There is no air path connecting the horizontal and vertical paths, the air streams cannot mix, the only connection is ‘heat’ transfer through the aluminium walls of the honeycomb component.

The horizontal airflow (left to right), is hot humid air that would normally exit the machine directly, but at 100% humidity, it is predominantly UFPs and contains a significant amount of VOCs.

The action of the cross-flow honeycomb heat exchanger significantly reduces the humidity level of the exit air and thus reduces the UFP and VOC content.

It will be appreciated that variants of the above-disclosed and other features and functions, or alternatives thereof, may be combined into many other different systems or applications. Various presently unforeseen or unanticipated alternatives, modifications, variations or improvements therein may be subsequently made by those skilled in the art which are also intended to be encompassed by the following claims.

What is claimed is:

1. A printing device having ultrafine particle (UFP) emissions, including:
an UFP particle removal assembly comprising a fluid conduit having a printing device emission input and output and an other fluid input and output wherein an emission portion of the conduit is affected by the other fluid portion and communication of the other fluid through the removal assembly effects a condensation/coalescence of the UFP emissions between the emission input and output for a reduction in UFP content of printing device emissions at the printing device emission output.

2. The printing device of claim 1 wherein the emission portion is sealed from the other fluid portion.

3. The printing device of claim 1 wherein the fluid conduit includes an interface between the emission portion and the other fluid portion for heat transfer from the emissions to the other fluid.

4. The printing device of claim 3 wherein the fluid conduit comprises a honeycomb.

5. The printing device of claim 4 wherein the interface comprises an aluminum wall of the honeycomb.

6. The printing device of claim 4 wherein the honeycomb comprises a cross-flow of the emissions and the other fluid.

7. The printing device of claim 6 wherein the emissions flow orthogonally relative to the other fluid through the honeycomb.

8. The printing device of claim 6 wherein the other fluid comprises ambient air.

9. The printing device of claim 3 wherein the emission portion is in a first plane of the removal assembly and the other fluid portion is in a second plane of the removal assembly.

10. An exhaust cooling and coalescing device for association with a printer for controlled capture and heat transfer processing, comprising:
a first plurality of conduits for communicating printer exhaust in a first direction;
a second plurality of conduits for communicating cooling ambient air, relative to the exhaust, in a second direction, the second plurality being interspersed within the first plurality; and,
an interface comprising a wall between the first and second conduits for effecting heat transfer from a one of the first conduit to a one of the second conduits whereby the heat transfer effects the cooling of the exhaust for coalescing of UFPs within the exhaust.

11. The device of claim 10 comprising a cross-flow honeycomb assembly.

12. The device of claim 10 wherein the first conduits are disposed orthogonally relative to the second conduits.
